(19) United States
(12) Patent Application Publication
(10) Pub. No.: US 2018/0041163 A1
(43) Pub. Date: Feb. 8, 2018

(54) PHOTOVOLTAIC STRING COMBINER WITH MODULAR PLATFORM ARCHITECTURE

(71) Applicant: ABB Schweiz AG, Baden (CH)

(72) Inventors: Paul M. White, Phoenix, AZ (US); Wisam M. Alhoor, Phoenix, AZ (US)

(21) Appl. No.: 15/549,226

(22) PCT Filed: Feb. 8, 2016
(86) PCT No.: PCT/US2016/016935

§ 371 Date: Aug. 7, 2017

Related U.S. Application Data
(60) Provisional application No. 62/112,685, filed on Feb. 6, 2015.

(51) Int. Cl. H02S 50/10; G01R 31/28; G01R 31/40

(52) U.S. Cl. CPC H02S 50/10; G01R 31/40; G01R 31/2836

(57) ABSTRACT

One or more techniques and/or systems are provided for managing a photovoltaic arrangement. A photovoltaic string combiner may be configured to combine a set of photovoltaic strings of the photovoltaic arrangement. The photovoltaic string combiner comprises a modular platform architecture configured to host one or monitoring modules in a plug and play manner based upon a drop in topology where a user may easily install or remove monitoring modules from the modular platform architecture. A monitoring module may automatically self-detect, such as during boot up, positional data (e.g., an indication that the monitoring module is to monitor a first set of 8 photovoltaic strings) and/or configuration data (e.g., calibration data, a grounded configuration, a floating configuration, etc.). The monitoring modules may provide positional data, configuration data, and/or measurement data (e.g., a current measurement from a photovoltaic string) to a main controller module that manages the photovoltaic arrangement.

### RELATED APPLICATIONS

This application claims priority to U.S. Provisional Application 62/112,685, titled “PHOTOVOLTAIC STRING COMBINER WITH MODULAR PLATFORM ARCHITECTURE” and filed on Feb. 6, 2015, which is incorporated herein by reference.

### BACKGROUND

Many electric systems may utilize photovoltaic arrangements, such as photovoltaic systems comprising solar panels that absorb and convert sunlight into electricity for power generation. An inverter may be configured to convert DC power from a photovoltaic arrangement to AC power for an AC power grid that may supply power to a building. The photovoltaic arrangement may comprise a plurality of photovoltaic strings that may be combined in parallel by a photovoltaic string combiner. A photovoltaic string may comprise a plurality of photovoltaic panels that are connected in series. The photovoltaic string combiner may be configured to measure current and/or obtain other information from the photovoltaic strings such as identification of a fault. Unfortunately, photovoltaic string combiners may be designed with a particular number of connections used to connect to photovoltaic stings (e.g., photovoltaic string combiners may be massed produced with the same configuration or may be custom made which may be prohibitively expensive), and thus a photovoltaic string combiner may be underutilized or unable to scale to support larger numbers of photovoltaic strings. If a single component is changed (e.g., replacement of a failed string monitoring interface board within the photovoltaic string combiner), then an entire photovoltaic system may need to be updated and/or recalibrated (e.g., due to analog signals connecting through the entire photovoltaic system), which may result in costly field calibration and service.

### SUMMARY

This summary is provided to introduce a selection of concepts in a simplified form that are further described below in the detailed description. This summary is not intended to identify key factors or essential features of the claimed subject matter, nor is it intended to be used to limit the scope of the claimed subject matter.

Among other things, one or more systems and/or techniques for managing a photovoltaic arrangement are provided herein. A photovoltaic string combiner may be configured to combine, such as in parallel, a set of photovoltaic strings of a photovoltaic arrangement. A photovoltaic string may comprise a plurality of photovoltaic panels connected in series. The photovoltaic string combiner may comprise a modular platform architecture configured to host one or more monitoring modules interconnected by a communication channel. Because the modular platform architecture may be configured according to a drop in topology (e.g., front facing hardware used to interface with monitoring modules), a monitoring module may be easily installed or removed from the modular platform architecture. In an example, a monitoring module may have a digital configuration so that the monitoring module may be installed according to a plug and play configuration where the monitoring module may become self-ware of its operating configuration and/or role within the photovoltaic string combiner without manual recalibration the photovoltaic string combiner.

In an example, the one or more monitoring modules may comprise a first monitoring module comprising a local processor. The local processor may be configured to self-detect first positional data (e.g., an installed position of the first monitoring module within the modular platform architecture, such as a first installation slot connected to a first set of 10 photovoltaic strings within the photovoltaic arrangement) and/or configuration data (e.g., whether the first monitoring module is grounded or floating) of the first monitoring module. The first local processor may be configured to obtain measurement data from the first set of 10 photovoltaic string connected to the first monitoring module (e.g., current measurements, detection of a fault or failure, etc.). The photovoltaic string combiner may comprise a main controller module connected to the modular platform architecture by the communication channel. The main controller module may be configured to determine a state of the photovoltaic arrangement based upon positional data, configuration data, and/or measurement data received from the one or more monitoring modules installed within the modular platform architecture. In an example, the state may indicate whether a photovoltaic string has a fault or is operating according to spec. In another example, the state may indicate a modular configuration of the modular platform architecture (e.g., a number of photovoltaic strings connected to the photovoltaic arrangement, a number of monitoring modules installed within the modular platform architecture, whether a monitoring module is grounded or floating, an installation or a removal of a monitoring module, etc.).

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a component block diagram illustrating an exemplary system for managing a photovoltaic arrangement.

FIG. 2A is a component block diagram illustrating an exemplary system for managing a photovoltaic arrangement, where positional data and configuration data is provided to a main controller module.

FIG. 2B is a component block diagram illustrating an exemplary system for managing a photovoltaic arrangement, where measurement data is provided to a main controller module.

FIG. 2C is a component block diagram illustrating an exemplary system for managing a photovoltaic arrangement, where a monitoring module is removed from a module platform architecture.

FIG. 2D is a component block diagram illustrating an exemplary system for managing a photovoltaic arrangement, where data is locally shared between monitoring modules.

FIG. 2E is a component block diagram illustrating an exemplary system for managing a photovoltaic arrangement, where a software update is performed for a monitoring module.

FIG. 2F is a component block diagram illustrating an exemplary system for managing a photovoltaic arrangement, where a new monitoring module is installed into a module platform architecture.

FIG. 3 is an illustration of an exemplary computing device-readable medium wherein processor-executable instructions configured to embody one or more of the provisions set forth herein may be comprised.

FIG. 4 illustrates an exemplary computing environment wherein one or more of the provisions set forth herein may be implemented.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide an understanding of the claimed subject matter. It may be evident, however, that the claimed subject matter may be practiced without these specific details. In other instances, structures and devices are illustrated in block diagram form in order to facilitate describing the claimed subject matter.

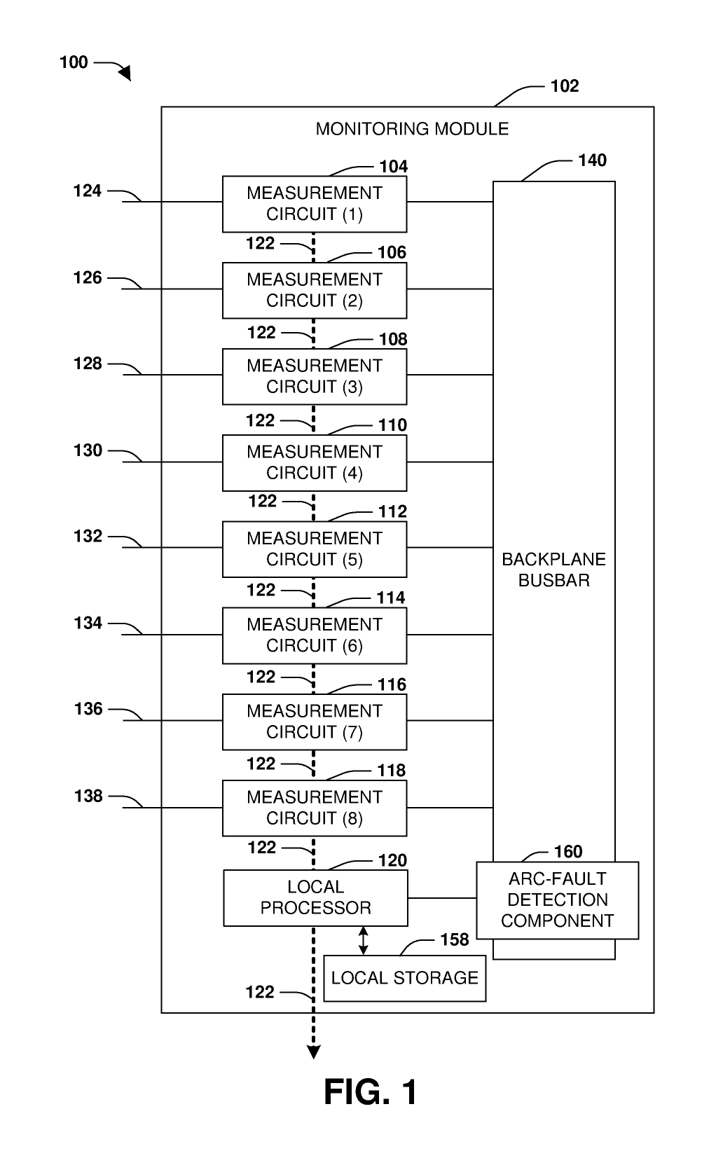

FIG. 1 illustrates an example of a system 100 comprising a monitoring module 102 that may be installed according to a plug and play configuration into a modular platform architecture of a photovoltaic string combiner. For example, the modular platform architecture may have a drop in topology with front facing hardware used to interface with the monitoring module 102. The monitoring module 102 may comprise a local processor 120. The local processor 120 may be configured to store information within local storage 158 of the monitoring module 102. The monitoring module 102 may comprise one or more measurement circuits comprising measurement components (e.g., a current measurement component, a fault detection component, etc.) and/or analog to digital converts, such as a first measurement circuit 104 connected to a first current measurement channel 124 of a first photovoltaic string, a second measurement circuit 106 connected to a second current measurement channel 126 of a second photovoltaic string, a third measurement circuit 108 connected to a third current measurement channel 128 of a third photovoltaic string, a fourth measurement circuit 110 connected to a fourth current measurement channel 130 of a fourth photovoltaic string, a fifth measurement circuit 112 connected to a firth current measurement channel 132 of a fifth photovoltaic string, a sixth measurement circuit 114 connected to a sixth current measurement channel 134 of a sixth photovoltaic string, a seventh measurement circuit 116 connected to a seventh current measurement channel 136 of a seventh photovoltaic string, an eighth measurement circuit 118 connected to an eighth current measurement channel 138 of an eighth photovoltaic string, and/or any other number of measurement circuits. The one or more measurement circuits may be connected to a backplane busbar 140 that provides a powered connection for the monitoring module 102. The one or more measurement circuits may be connected to the local processor 120 by a communication channel 122, such as a voltage isolated digital communication channel. In an example, the measurement circuits may be connected to the photovoltaic strings by one or more fuses.

In an example, the first measurement circuit 104 may comprise a first current measurement component configured to measure current of the first photovoltaic string over the first current measurement channel 124. The first measurement circuit 104 may comprise an analog to digital converter for the first current measurement channel 124 that converts an analog signal from the first current measurement channel 124 to a digital signal. In an example, the first measurement circuit 104 may locally store calibration data within the first current measurement channel 124. In this way, the one or more measurement circuits may collect measurement data of the photovoltaic strings, such as current measurement data, and provide the measurement data to the local processor 120 over the communication channel 122.

The local processor 120 may store the measurement data within the local storage 158 and/or may provide the measurement data over the communication channel 122 to a main controller module of the photovoltaic string combiner. The local processor 120 may be configured to self-detect positional data of the monitoring module 102 within the modular platform architecture (e.g., a position bus of the photovoltaic string combiner may be evaluated to identify an installation slot, of the modular platform architecture, within which the monitoring module 102 is installed) and/or configuration data of the monitoring module 102 (e.g., whether the monitoring module 102 has a grounded configuration or a floating configuration). The local processor 120 may store the positional data and/or the configuration data within the local storage 158 and/or may provide the positional data and/or the configuration data over the communication channel 122 to the main controller module.

In an example, the monitoring module 102 may comprise an arc-fault detection component 160. The arc-fault detection component 160 may be configured to detect at least one of a parallel arc-fault or a series arc-fault associated with a photovoltaic string, the monitoring module 102, and/or the photovoltaic string combiner.

In an example, the local processor 120 may be configured to obtain a temperature measurement of the monitoring module 102. The local processor 120 may be configured to recalibrate the monitoring module 102 based upon the temperature measurement.

In an example, the local processor 120 may be configured to receive a remote software update command such as from the main controller module over the communication channel 122. The local processor 120 may be configured to update the monitoring module 102 based upon the remote software update command (e.g., modification of parameters and/or functionality used to obtain and/or evaluate measurement data).

In may be appreciated that while the monitoring module 102 is described as having current measurement capabilities, that a monitoring module may be configured with a wide variety of capabilities, such as user communication capabilities, fault detection capabilities, photovoltaic string management capabilities, etc.

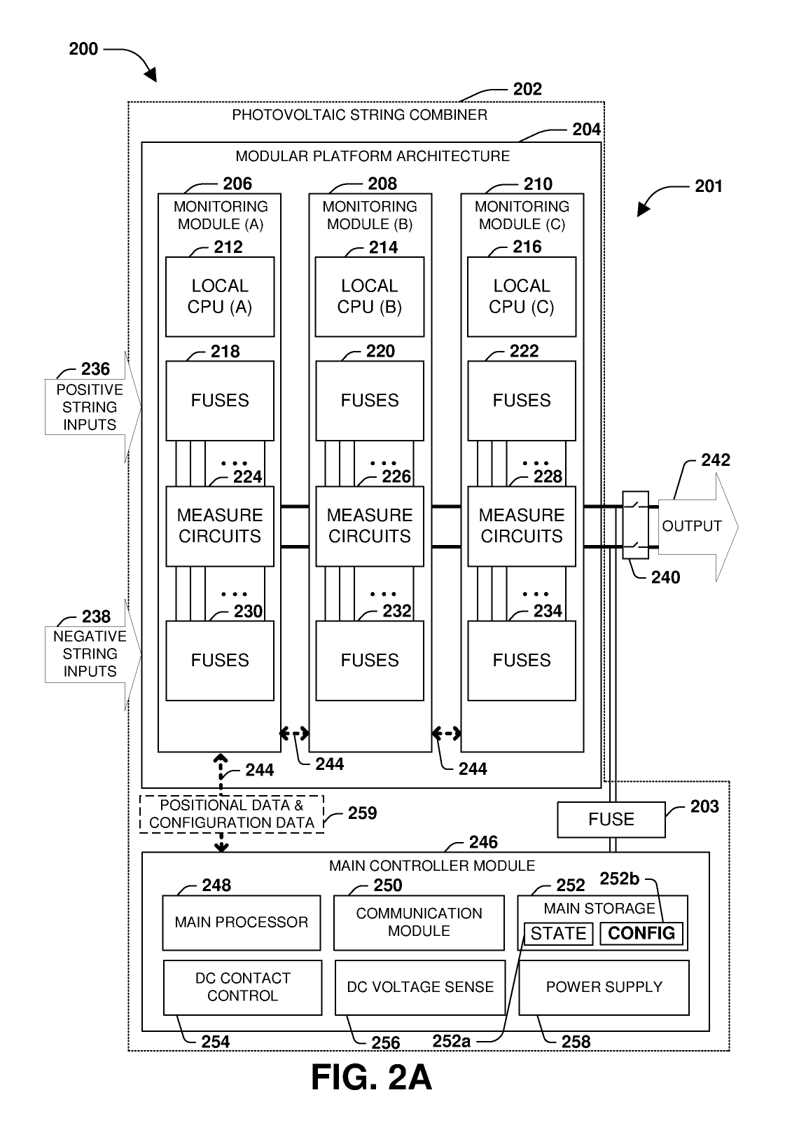

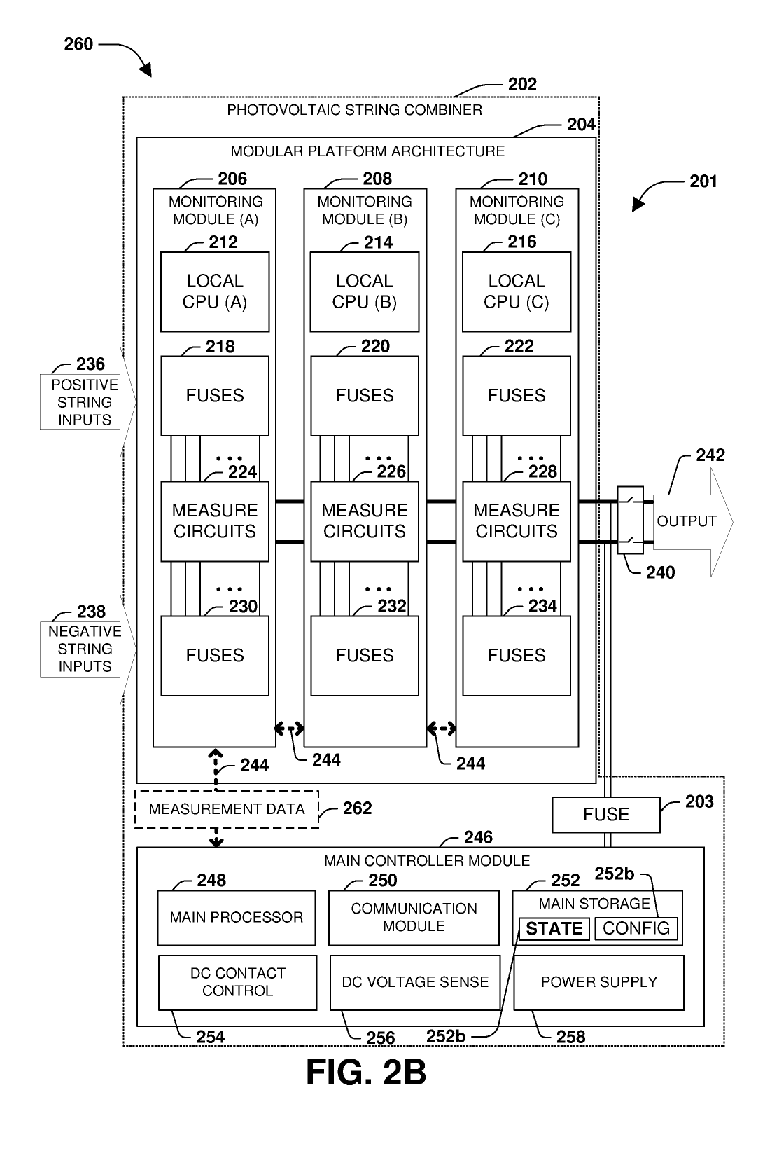

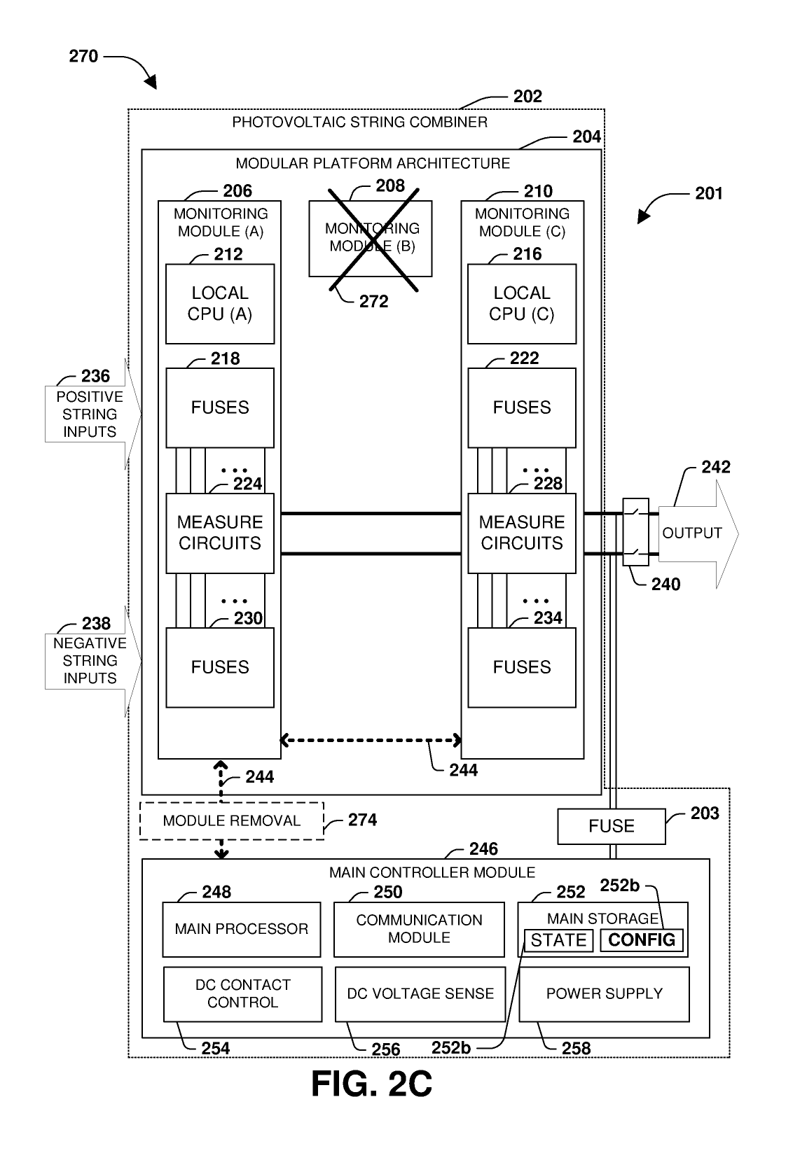

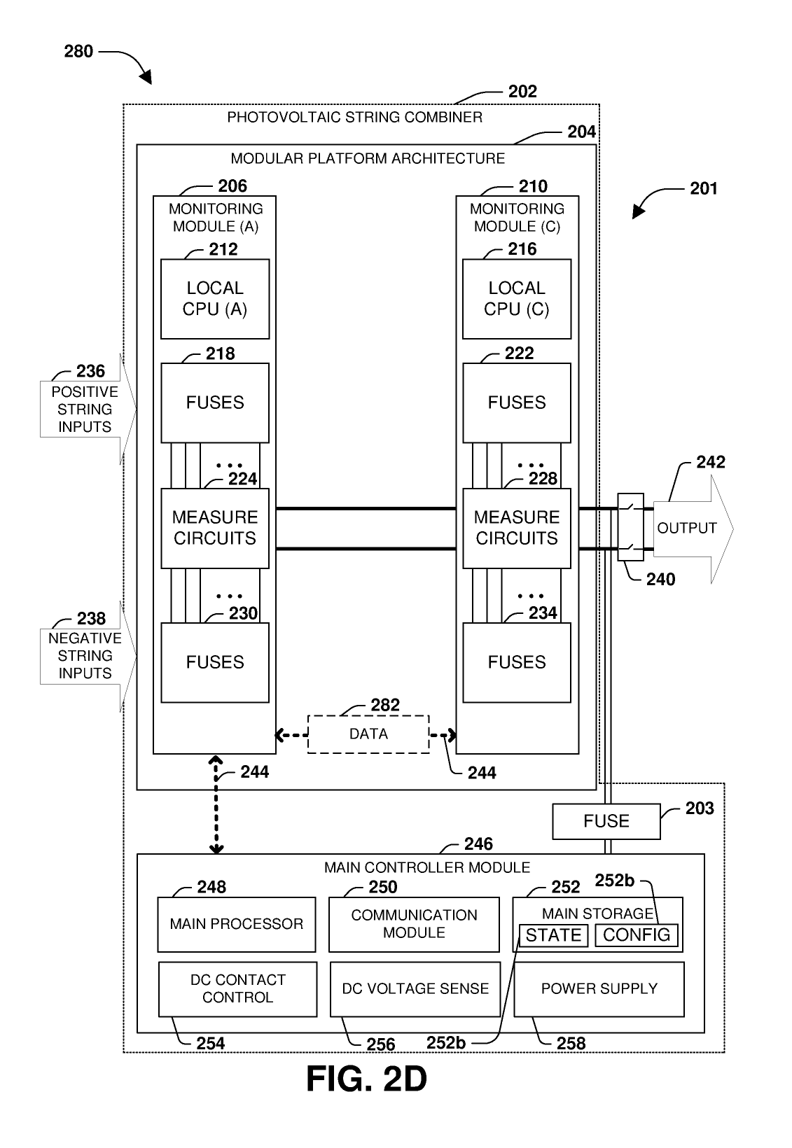

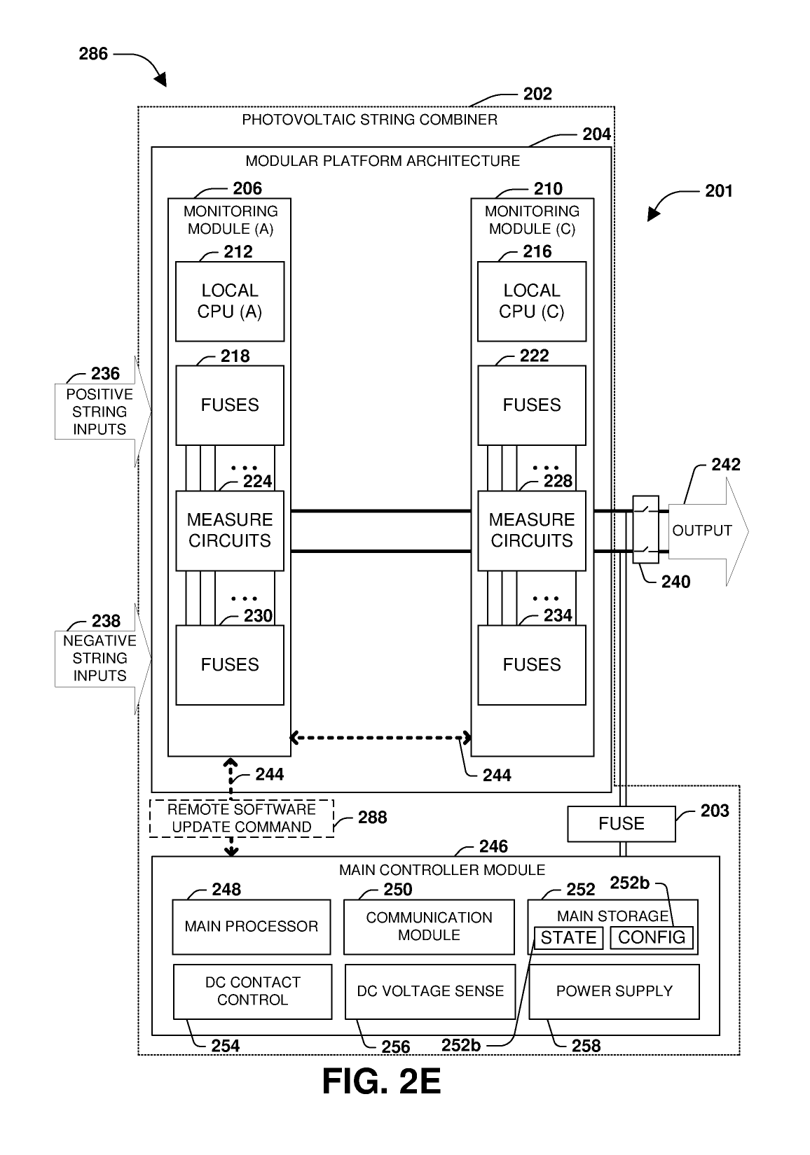

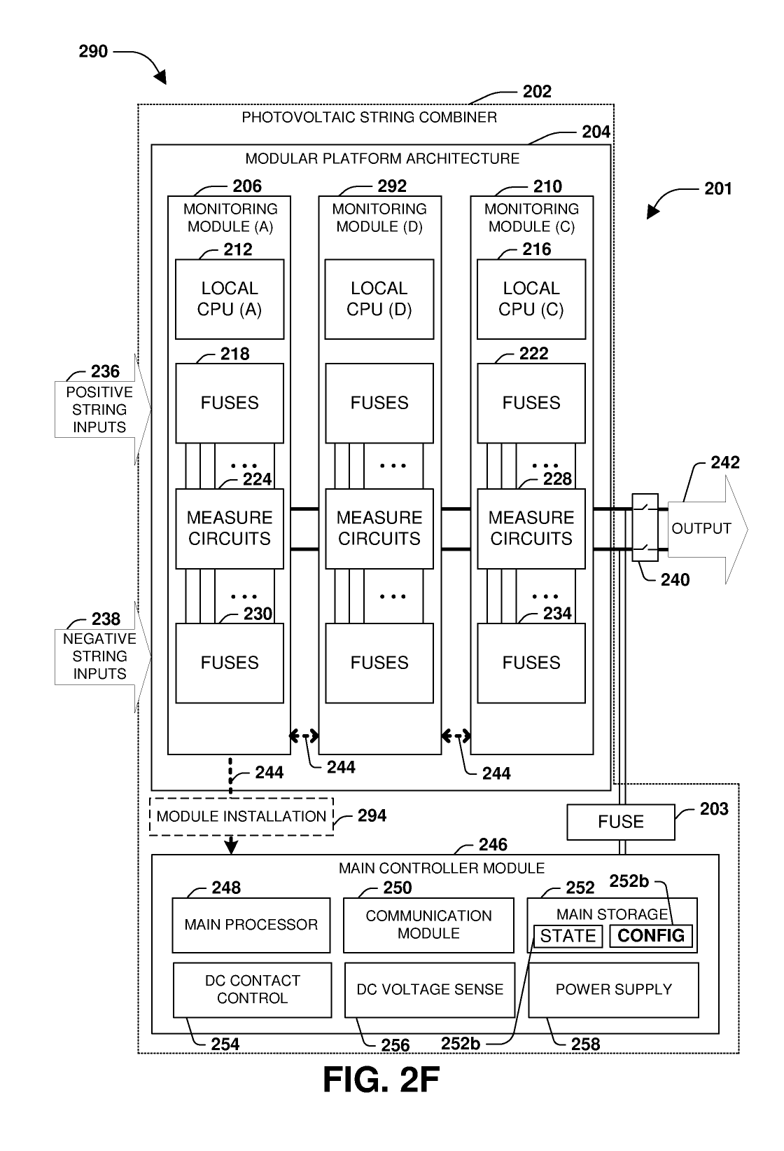

FIGS. 2A-2F illustrate examples of a system 201 for photovoltaic arrangement management. FIG. 2A illustrates an example 200 of the system 201 comprising a photovoltaic string combiner 202. The photovoltaic string combiner 202 may be configured to combine a set of photovoltaic strings (e.g., a photovoltaic string comprising a plurality of photovoltaic panels connected in series) of a photovoltaic arrangement, such as in parallel by connecting to positive string inputs 236 and negative string inputs 238 of the set of photovoltaic strings. The photovoltaic string combiner 202 may provide an output 242 from the photovoltaic arrangement such as to an inverter that converts DC power from the photovoltaic arrangement to AC power (e.g., AC power provided to an AC power grid that may supply power to a building). A disconnect 240 may be provided to disconnect the output 242 from the photovoltaic string combiner 202 (e.g., in response to a shutdown command).

The photovoltaic string combiner 202 may comprise a modular platform architecture 204 (e.g., a drop in topology with front facing hardware such that monitoring modules may be relatively easy to swap in and out of the modular platform architecture 204). The modular platform architecture 204 may be configured host one or more monitoring modules interconnected by a communication channel 244, such as a voltage isolated digital communication channel. For example, monitoring modules may be installed in a plug and play manner where a newly installed monitoring module may automatically become self-aware of its operating parameters (e.g., a position of the monitoring module within the modular platform architecture 204, a configuration of the monitoring module such as a grounded configuration or a floating configuration, calibration data of the monitoring module, and/or a role of the monitoring module in managing and monitoring the photovoltaic arrangement) and/or where the photovoltaic string combiner 202 can automatically self-detect and/or adjust management of the photovoltaic arrangement based upon information received from monitoring modules. In an example, a monitoring module (A) 206, a monitoring module (B) 208, a monitoring module (C) 210, and/or any other number of monitoring modules may be installed into the modular platform architecture 204. Power may be provide to the monitoring modules by a backplane busbar.

The monitoring module (A) 206 may comprise a local processor (A) 212 and a first set of measurement circuits 224 (e.g., a current measurement component and an analog to digital converter for a current measurement channel associated with a photovoltaic string) connected to the positive string inputs 236, such as through fuses 218, and connected to the negative string inputs 238, such as through fuses 230 (e.g., positive and negative string inputs for a first set of 8 photovoltaic strings of the photovoltaic arrangement). The monitoring module (B) 208 may comprise a local processor (B) 214 and a second set of measurement circuits 226 connected to the positive string inputs 236, such as through fuses 220, and connected to the negative string inputs 238, such as through fuses 232 (e.g., positive and negative string inputs for a second set of 8 photovoltaic strings of the photovoltaic arrangement). The monitoring module (C) 210 may comprise a local processor (C) 216 and a third set of measurement circuits 228 connected to the positive string inputs 236, such as through fuses 222, and connected to the negative string inputs 238, such as through fuses 234 (e.g., positive and negative string inputs for a third set of 8 photovoltaic strings of the photovoltaic arrangement).

The monitoring module (A) 206 may self-detect (e.g., automatically during installation and/or boot up) first positional data of the monitoring module (A) 206 within the modular platform architecture 204, such as by evaluating a positional bus. The first positional data may indicate that the monitoring module (A) 206 is installed within a first installation slot and is connected to the first set of 8 photovoltaic strings. The monitoring module (A) 206 may self-detect (e.g., automatically during installation and/or boot up) first configuration data such as whether the monitoring module (A) 206 is grounded or floating. The monitoring module (B) 208 may self-detect (e.g., automatically during installation and/or boot up) second positional data of the monitoring module (B) 208 within the modular platform architecture 204, such as by evaluating the positional bus. The second positional data may indicate that the monitoring module (B) 208 is installed within a second installation slot and is connected to the second set of 8 photovoltaic strings. The monitoring module (B) 208 may self-detect (e.g., automatically during installation and/or boot up) second configuration data such as whether the monitoring module (B) 208 is grounded or floating. The monitoring module (C) 210 may self-detect (e.g., automatically during installation and/or boot up) third positional data of the monitoring module (C) 210 within the modular platform architecture 204, such as by evaluating the positional bus. The third positional data may indicate that the monitoring module (C) 210 is installed within a third installation slot and is connected to the third set of 8 photovoltaic strings. The monitoring module (C) 210 may self-detect (e.g., automatically during installation and/or boot up) third configuration data such as whether the monitoring module (C) 210 is grounded or floating. The monitoring module (A) 206, the monitoring module (B) 208, and/or the monitoring module (C) 210 may locally store positional data and/or configuration data (e.g., within local storage, within a current measurement channel, etc.).

The monitoring module (A) 206, the monitoring module (B) 208, and/or the monitoring module (C) 210 may send data 259, such as positional data and/or configuration data self-detected by the monitoring modules, to a main controller module 246 of the photovoltaic string combiner 202. The main controller module 246 may comprise a main processor 248, a DC contact control component 254 (e.g., the main controller module 246 and/or a monitoring module may command the DC contact control component 254 to open in case of a fault such as an over current fault or an over temperature fault, a DC voltage sense component 256 used such as in conjunction with current measurement data to detect an error in operation of a photovoltaic panel, a communication module 250, a power supply 258 used to provide power to the main controller module 246, and/or main storage 252. In an example the main controller module 246 may be connected to the output 242 of the photovoltaic string combiner 202 such as through a fuse 203. The main controller module 246 may receive the data 259 from the monitoring modules over the communication channel 244. The main controller module 246 may store the data 259 within the main storage 252. In an example, the main controller module 246 may evaluate the positional data and the configuration data to identify a modular configuration 252b of the modular platform architecture 204. For example, the modular configuration 252b may indicate that the photovoltaic string combiner 202 comprises 3 grounded monitoring modules and combines 24 photovoltaic strings corresponding to the first, second, and third set of 8 photovoltaic strings.

FIG. 2B illustrates an example 260 of the monitoring module (B) 208 providing measurement data 262 to the main controller module 246. For example, the second set of measurement circuits 226 may be configured to obtain measurement data 262, such as current measurements or any other type of measurements (e.g., a voltage measurement, an operating parameter of a photovoltaic panel, a determination as to whether a photovoltaic panel has a fault, etc.), from the second set of 8 photovoltaic strings. In an example, the local processor (B) 214 may locally store the measurement data 262 within the monitoring module (B) 208 (e.g., within local storage or within a current measurement channel). In another example, the local processor (B) 214 may share the measurement data 262 with other monitoring modules by sending the measurement data 262 over the communication channel 244 to the monitoring module (A) 206 and/or the monitoring module (C) 210.

The local processor (B) 214 may send the measurement data 262 over the communication channel 244 to the main controller module 246 (e.g., the communication module 250 may receive the measurement data 262 for access by the main processor 248). The measurement data 262 may be stored within the main storage 252. The main controller module 246 (e.g., the main processor 248, the DC contact control component 254, the DC voltage sense component 256, etc.) may perform post processing on the measurement data 262. In an example, the main controller module 246 may scale the measurement data 262 to create scaled measurement data. In another example, the main controller module 246 may evaluate the measurement data 262 (e.g., and/or the data 259 comprising the positional data and the configuration data of FIG. 2A) to determine a state 252b of the photovoltaic arrangement. The state 252b may indicate whether a fault occurred for the second set of 8 photovoltaic strings, whether the second of 8 photovoltaic strings are operating according to spec or out of spec, and/or other information about the second set of 8 photovoltaic strings (e.g., information about whether there is an arcing or connection issue with a photovoltaic string). In this way, the main controller module 246 may automatically become aware of the modular platform architecture 204 (e.g., a number and configuration of monitoring modules), the photovoltaic arrangement (e.g., a number of photovoltaic strings) and/or operating conditions of the photovoltaic arrangement (e.g., current measurement data, a detected fault, a newly installed photovoltaic panel, a removal of a photovoltaic panel, etc.).

FIG. 2C illustrates an example 270 of the main controller module 246 detecting 274 a removal 272 of the monitoring module (B) 208. Because the modular platform architecture 204 may provide front facing hardware with a drop in topology, a user may easily install or remove monitoring modules from the modular platform architecture 204, such as removing 272 the monitoring module (B) 208 from the modular platform architecture 204. The main controller module 246 may detect 274 the removal 272 based upon various indicators such as a loss of a heartbeat signal from the monitoring module (B) 208, a communication timeout with respect to the monitoring module (B) 208, etc. The main controller module 246 may update the modular configuration 252b based upon the removal 272 to indicate that the modular platform architecture 204 comprises the monitoring module (A) 206 that monitors the first set of 8 photovoltaic strings and the monitoring module (C) 210 that monitors the third set of 8 photovoltaic strings but not the monitoring module (B) 208.

FIG. 2D illustrates an example 280 of the monitoring module (C) 210 sending data 282 to the monitoring module (A) 206 over the communication channel 244. For example, the data 282 may comprise positional data of the monitoring module (C) 210 within the modular platform architecture 204 (e.g., that the monitoring module (C) 210 is installed in the third installation slot and is connected to the third set of 8 photovoltaic strings), configuration data of the monitoring module (C) 210 (e.g., whether the monitoring module (C) 201 has a grounded configuration or a floating configuration), measurement data obtained by the third set of measurement circuits 228, and/or other operational and calibration information of the monitoring module (C) 210. In this way, monitoring modules may locally share information with one another.

FIG. 2E illustrates an example 286 of the monitoring module (A) 206 performing a software update. For example, the main controller module 246 may receive a remote software update command 288 from a remote source (e.g., the communication module 250 may receive the remote software update command 288 wirelessly or over a network from a computing device). The main controller module 246 may send the remote software update command 288 over the communication channel 244 to the monitoring module (A) 206. The monitoring module (A) 206 may perform the software update based upon the remote software update command 288 (e.g., the monitoring module (A) 206 may update calibration data, parameters and/or functionality used to obtain and evaluate measurement data from photovoltaic strings, configuration data, etc.).

FIG. 2F illustrates an example 290 of the main controller module 246 detecting 294 an installation of a new monitoring module (D) 292 within the modular platform architecture 204. Because the modular platform architecture 204 may provide front facing hardware with a drop in topology, a user may easily install or remove monitoring modules from the modular platform architecture 204, such as installing the new monitoring module (D) 292 into the second installation slot of the modular platform architecture 204 (e.g., as a replacement for the monitoring module (B) 208 that was previously removed from the second installation slot). Upon boot up, a local processor (D) of the new monitoring module (D) 292 may self-detect positional data, indicating that the new monitoring module (D) 292 is installed in the second installation slot and is connected to the second set of 8 photovoltaic strings, (e.g., utilizing a positional bus), and/or configuration data indicating that the new monitoring module (D) 292 has a grounded configuration. The local processor (D) may calibrate a set of measurement circuits for obtaining measurement data from the second set of 8 photovoltaic strings. The local processor (D) may send a notification to the main controller module 246 of the installation of the new monitoring module (D) 292. The notification may comprise the positional data and/or the configuration data. The main controller module 246 may update the modular configuration 252b to indicate that the modular platform architecture 204 now also comprises the monitoring module (D) 292 connected to the second set of 8 photovoltaic strings.

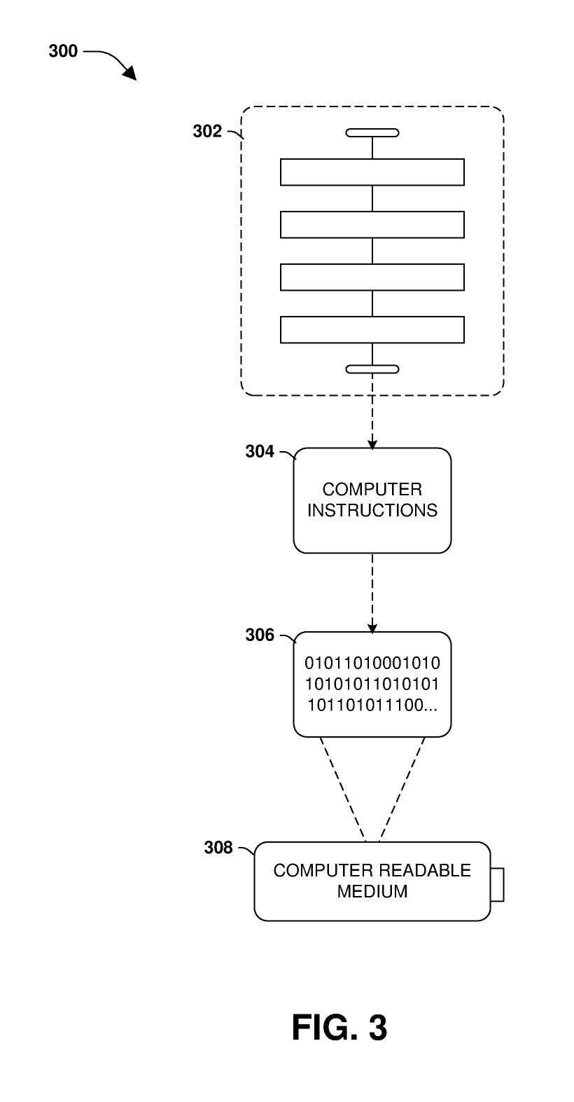

Still another embodiment involves a computer-readable medium comprising processor-executable instructions configured to implement one or more of the techniques presented herein. An example embodiment of a computer-readable medium or a computer-readable device is illustrated in FIG. 3, wherein the implementation 300 comprises a computer-readable medium 308, such as a CD-R, DVD-R, flash drive, a platter of a hard disk drive, etc., on which is encoded computer-readable data 306. This computer-readable data 306, such as binary data comprising at least one of a zero or a one, in turn comprises a set of computer instructions 304 configured to operate according to one or more of the principles set forth herein. In some embodiments, the processor-executable computer instructions 304 are configured to perform a method 302. In some embodiments, the processor-executable instructions 304 are configured to implement a system, such as at least some of the exemplary system 100 of FIG. 1 and/or at least some of the exemplary system 201 of FIGS. 2A-2F, for example. Many such computer-readable media are devised by those of ordinary skill in the art that are configured to operate in accordance with the techniques presented herein.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

As used in this application, the terms “component,” “module,” “system”, “interface”, and/or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, many modifications may be made to this configuration without departing from the scope or spirit of the claimed subject matter.

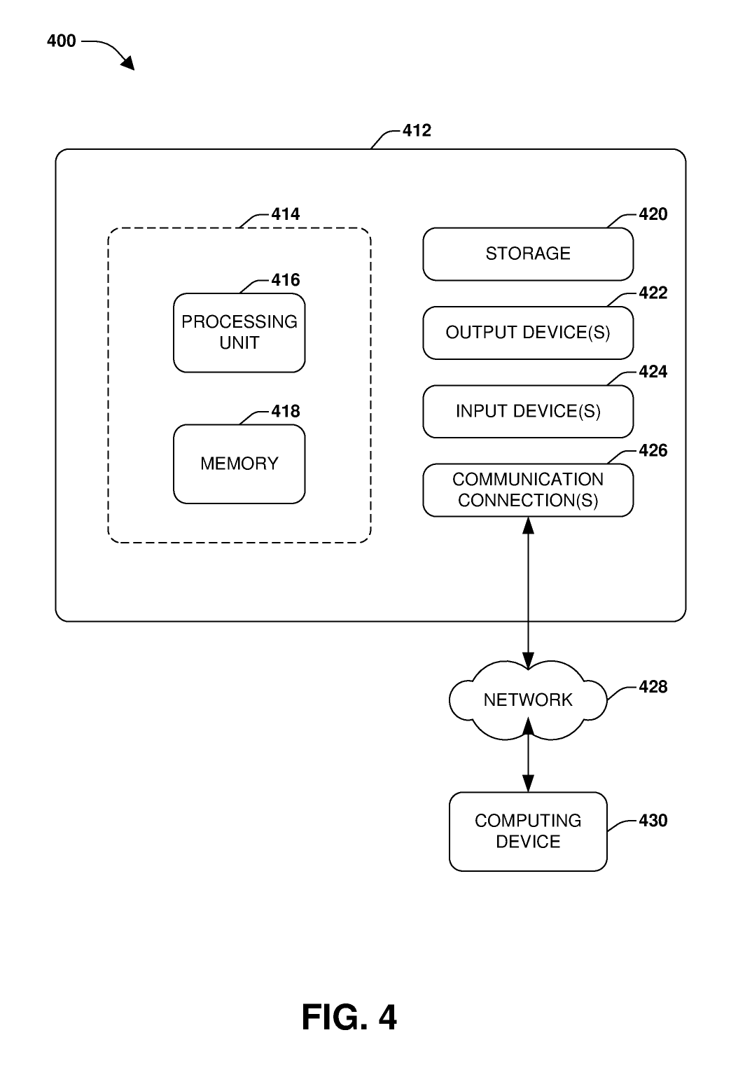

FIG. 4 and the following discussion provide a brief, general description of a suitable computing environment to implement embodiments of one or more of the provisions set forth herein. The operating environment of FIG. 4 is only one example of a suitable operating environment and is not intended to suggest any limitation as to the scope of use or functionality of the operating environment. Example computing devices include, but are not limited to, personal computers, server computers, hand-held or laptop devices, mobile devices (such as mobile phones, Personal Digital Assistants (PDAs), media players, and the like), multiprocessor systems, consumer electronics, mini computers, mainframe computers, distributed computing environments that include any of the above systems or devices, and the like.

Although not required, embodiments are described in the general context of “computer readable instructions” being executed by one or more computing devices. Computer readable instructions may be distributed via computer readable media (discussed below). Computer readable instructions may be implemented as program modules, such as functions, objects, Application Programming Interfaces (APIs), data structures, and the like, that perform particular tasks or implement particular abstract data types. Typically, the functionality of the computer readable instructions may be combined or distributed as desired in various environments.

FIG. 4 illustrates an example of a system 400 comprising a computing device 412 configured to implement one or more embodiments provided herein. In one configuration, computing device 412 includes at least one processing unit 416 and memory 418. Depending on the exact configuration and type of computing device, memory 418 may be volatile (such as RAM, for example), non-volatile (such as ROM, flash memory, etc., for example) or some combination of the two. This configuration is illustrated in FIG. 4 by dashed line 414.

In other embodiments, device 412 may include additional features and/or functionality. For example, device 412 may also include additional storage (e.g., removable and/or non-removable) including, but not limited to, magnetic storage, optical storage, and the like. Such additional storage is illustrated in FIG. 4 by storage 420. In one embodiment, computer readable instructions to implement one or more embodiments provided herein may be in storage 420. Storage 420 may also store other computer readable instructions to implement an operating system, an application program, and the like. Computer readable instructions may be loaded in memory 418 for execution by processing unit 416, for example.

The term “computer readable media” as used herein includes computer storage media. Computer storage media includes volatile and nonvolatile, removable and non-removable media implemented in any method or technology for storage of information such as computer readable instructions or other data. Memory 418 and storage 420 are examples of computer storage media. Computer storage media includes, but is not limited to, RAM, ROM, EEPROM, flash memory or other memory technology, CD-ROM, Digital Versatile Disks (DVDs) or other optical storage, magnetic cassettes, magnetic tape, magnetic disk storage or other magnetic storage devices, or any other medium which can be used to store the desired information and which can be accessed by device 412. Computer storage media does not, however, include propagated signals. Rather, computer storage media excludes propagated signals. Any such computer storage media may be part of device 412.

Device 412 may also include communication connection(s) 426 that allows device 412 to communicate with other devices. Communication connection(s) 426 may include, but is not limited to, a modem, a Network Interface Card (NIC), an integrated network interface, a radio frequency transmitter/receiver, an infrared port, a USB connection, or other interfaces for connecting computing device 412 to other computing devices. Communication connection(s) 426 may include a wired connection or a wireless connection. Communication connection(s) 426 may transmit and/or receive communication media.

The term “computer readable media” may include communication media. Communication media typically embodies computer readable instructions or other data in a “modulated data signal” such as a carrier wave or other transport mechanism and includes any information delivery media. The term “modulated data signal” may include a signal that has one or more of its characteristics set or changed in such a manner as to encode information in the signal.

Device 412 may include input device(s) 424 such as keyboard, mouse, pen, voice input device, touch input device, infrared cameras, video input devices, and/or any other input device. Output device(s) 422 such as one or more displays, speakers, printers, and/or any other output device may also be included in device 412. Input device(s) 424 and output device(s) 422 may be connected to device 412 via a wired connection, wireless connection, or any combination thereof. In one embodiment, an input device or an output device from another computing device may be used as input device(s) 424 or output device(s) 422 for computing device 412.

Components of computing device 412 may be connected by various interconnects, such as a bus. Such interconnects may include a Peripheral Component Interconnect (PCI), such as PCI Express, a Universal Serial Bus (USB), firewire (IEEE 1394), an optical bus structure, and the like. In another embodiment, components of computing device 412 may be interconnected by a network. For example, memory 418 may be comprised of multiple physical memory units located in different physical locations interconnected by a network.

Those skilled in the art will realize that storage devices utilized to store computer readable instructions may be distributed across a network. For example, a computing device 430 accessible via a network 428 may store computer readable instructions to implement one or more embodiments provided herein. Computing device 412 may access computing device 430 and download a part or all of the computer readable instructions for execution. Alternatively, computing device 412 may download pieces of the computer readable instructions, as needed, or some instructions may be executed at computing device 412 and some at computing device 430.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Further, unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “exemplary” is used herein to mean serving as an example, instance, illustration, etc., and not necessarily as advantageous. As used herein, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B and/or both A and B. Furthermore, to the extent that “includes”, “having”, “has”, “with”, and/or variants thereof are used in either the detailed description or the claims, such terms are intended to be inclusive in a manner similar to the term “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A system for managing a photovoltaic arrangement, comprising:
a photovoltaic string combiner configured to combine a set of photovoltaic strings of a photovoltaic arrangement, the photovoltaic string combiner comprising:
a modular platform architecture configured to host one or more monitoring modules interconnected by a communication channel, the one or more monitoring modules comprising a first monitoring module comprising a first local processor configured to:
self-detect at least one of first positional data of the first monitoring module within the modular platform architecture or first configuration data of the first monitoring module; and
obtain first measurement data from a first photovoltaic string connected to the first monitoring module; and
a main controller module, connected to the modular platform architecture by the communication channel, configured to determine a state of the photovoltaic arrangement based upon at least one of positional data, configuration data, or measurement data received from the one or more monitoring modules.

2. The system of claim 1, the photovoltaic string combiner comprising:
an arc-fault detection component configured to detect at least one of a parallel arc-fault or a series arc-fault associated with the photovoltaic arrangement.

3. The system of claim 1, the one or more monitoring modules comprising a second monitoring module configured to:
self-detect at least one of second positional data of the second monitoring module within the modular platform architecture or second configuration data of the second monitoring module;
obtain second measurement data from a second photovoltaic string connected to the second monitoring module; and
communicate at least one of the second positional data, the second configuration data, or the second measurement data to the main controller module.

4. The system of claim 3, the second monitoring module configured to:
communicate at least one of the second positional data, the second configuration data, or the second measurement data to the first monitoring module.

5. The system of claim 1, the first monitoring module comprising local storage within which the first monitoring module stores at least one of the first positional data, the first configuration data, or the first measurement data.

6. The system of claim 1, the first configuration data indicating whether the first monitoring module has a grounded configuration or a floating configuration.

7. The system of claim 1, the main controller module configured to:
determine a number of photovoltaic strings of the photovoltaic arrangement based upon the positional data received from the one or more monitoring modules.

8. The system of claim 1, the main controller module configured to:
determine a modular configuration of the modular platform architecture based upon at least one of the positional data or the configuration data received from the one or more monitoring modules.

9. The system of claim 8, the main controller module configured to:
update the modular configuration based upon a determination that a new monitoring module has been installed into the modular platform architecture.

10. The system of claim 8, the main controller module configured to:
update the modular configuration based upon a determination that a target monitoring module has been removed from the modular platform architecture.

11. The system of claim 1, the communication channel comprising a voltage isolated digital communication channel.

12. The system of claim 1, the photovoltaic string combiner comprising a backplane busbar providing a powered connection between the one or more monitoring modules.

13. The system of claim 1, the first monitoring module comprising a current measurement component configured to measure current of the first photovoltaic string over a first current measurement channel.

14. The system of claim 13, the first local processor comprising an analog to digital converter for the first current measurement channel.

15. The system of claim 1, the first local processor configured to perform recalibration of the first monitoring module based upon a temperature measurement of the first monitoring module.

16. The system of claim 1, the main controller module configured to:
scale the first measurement data to create scaled first measurement data.

17. The system of claim 1, the first local processor configured to perform a software update for the first monitoring module based upon receipt of a remote software update command from the main controller module.

18. A system for managing a photovoltaic arrangement, comprising:
a monitoring module configured for modular installation within a modular platform architecture of a photovoltaic string combiner, the monitoring module comprising a local processor configured to:
utilize a position bus of the modular platform architecture to determine positional data of the monitoring module within the modular platform architecture;
identify configuration data of the first monitoring module, the configuration data indicating whether the first monitoring module has a grounded configuration or a floating configuration;
obtain current measurement data of a photovoltaic string connected to the first monitoring module; and
provide at least one of the positional data, the configuration data, or the current measurement data to a main controller module of the photovoltaic string combiner.

19. A system for managing a photovoltaic arrangement, comprising:
a photovoltaic string combiner configured to combine a set of photovoltaic strings of a photovoltaic arrangement, the photovoltaic string combiner comprising:
a main controller module, connected to a modular platform architecture, configured to:
receive positional data and configuration data from one or more monitoring modules connected to the modular platform architecture;
determine a modular configuration of the modular platform architecture based upon the positional data and configuration data, the modular configuration indicative of a number of photovoltaic strings connected to the modular platform architecture; and
determine a state of the photovoltaic arrangement based upon measurement data received from the one or more monitoring modules.

20. The system of claim 19, the main controller module configured to:
responsive to detecting at least one of installation of a new monitoring module or removal of a monitoring module, update the modular configuration.
